(19) United States
(12) Patent Application Publication
(10) Pub. No.: US 2026/0173835 A1
(43) Pub. Date: Jun. 18, 2026

(54) A method of producing semiconductor devices comprising low dielectric constant thin films

(71) Applicant: Pibond Oy, Espoo (FI)

(72) Inventors: Thomas Gädda, Espoo (FI); Jagadish Salunke, Espoo (FI); Hanna Luusua, Espoo (FI); Kimmo Karaste, Espoo (FI); Zhongmei Han, Espoo (FI); Juha Rantala, Espoo (FI)

(21) Appl. No.: 19/119,832

(22) PCT Filed: Oct. 12, 2023
(86) PCT No.: PCT/FI2023/050583

§ 371 Date: Apr. 10, 2025

(30) Foreign Application Priority Data
Oct. 12, 2022 (FI) 20225923

(51) Int. Cl. H10W 20/00; C08G 77/50; H10P 14/692

(52) U.S. Cl. CPC H10W 20/077; C08G 77/50; H10P 14/6922

(57) ABSTRACT

A method of manufacturing a semiconductor device comprising a polymer film comprising a polymer obtained by polymerization of compounds having the general formula (I): X¹mR¹₃₋ₘSi—R³—(R⁵₂Si—O)ₙ—Si—R⁴—SiX²ₚR²_{3-P} wherein each X¹ and X² is independently selected from the group of hydrogen and organic or inorganic hydrolyzable groups; each R¹ and R² is independently selected from the group of hydrocarbyl residues; each R³ and R⁴ is independently selected from the group of alkylene having 1 to 6 carbon atoms and arylene having 6 to 10 carbon atoms; each R⁵ is selected from alkyl groups having 1 to 4 carbon atoms and phenyl groups; n is an integer of 1 to 5; m is an integer of 1 to 3; and p is an integer of 1 to 3. The polymer films are used as low dielectric constant films in semiconductor devices, in particular as barrier layers for filling spaces between metal interconnects.

### FIELD OF THE INVENTION

The present invention relates to a method of manufacturing a semiconductor device comprising a low dielectric constant thin film comprising polysiloxanes. The present invention also concerns uses of polymeric films in semiconductor devices.

### BACKGROUND

Built on semiconductor substrates, integrated circuits comprise millions of transistors and other devices, which communicate electrically with one another and with outside packaging materials through multiple levels of vertical and horizontal wiring embedded in a dielectric material. Within the metallization structure, “vias” make up the vertical wiring, whereas “interconnects” form the horizontal wiring. Fabricating the metallization can involve the successive depositing and patterning of multiple layers of dielectric and metal to achieve electrical connection among transistors and to outside packaging material. The patterning for a given layer is often performed by a multi-step process comprising layer deposition, photoresist spin, photoresist exposure, photoresist develop, layer etch, and photoresist removal on a substrate. Alternatively, the metal may sometimes be patterned by first etching patterns into a layer of a dielectric material, filling the pattern with metal, then subsequently chemically/mechanically polishing the metal so that the metal remains embedded only in the openings of the dielectric.

As an interconnect material, aluminum has been utilized for many years due to its high conductivity, good adhesion to SiO₂, known processing methods (sputtering and etching) and low cost. Initially, aluminum alloys have also been developed over the years to improve the melting point, diffusion, electromigration and other qualities as compared to pure aluminum. Spanning successive layers of aluminum, tungsten has traditionally served as the conductive via plug material. The drive to faster microprocessors and more powerful electronic devices have resulted in increasingly high circuit densities and faster operating speeds which—in turn—have required that higher conductivity metals and improved dielectrics with lower dielectric constants compared to silicon dioxide (preferably below 3.0) are used. After aluminum metallization the industry moved to copper damascene processes, where copper (or a copper alloy) is used for the higher conductance in the conductor lines and a spin-on or CVD process is used for producing low-k dielectrics which can be employed for the insulating material surrounding the conductor lines. To circumvent problems with etching, copper along with a barrier metal is blanket deposited over recessed dielectric structures consisting of interconnect and via openings and subsequently polished in a processing method known as the “dual damascene.” The bottom of the via opening is usually the top of an interconnect from the previous metal layer or, in some instances, the contacting layer to the substrate.

The copper “dual damascene” process has been utilized by the industry two decades successfully. The critical dimensions of copper interconnects in future devices will reach 10-20 nm, or even below. Consequently, the dielectric material between the interconnects are exhibiting similar critical dimensions. For the copper “dual damascene” process, this is in part very problematic since copper ions are very mobile which means that these ions will migrate to the dielectric layers. Eventually, an increase copper ion concentration will lead to dielectric breakdown leading the device or transistor non-operational. To prevent copper ion migration, various barrier layers have been deposited, which typically are nitrides of titanium of tantalum. In a sub 30 nm pitch design, the barrier layers would fill most of the space between the metal interconnects thus leading to an inadequate dielectric layer due to poor dielectric properties of said nitrides. Due to the above-mentioned challenges, there is an on-going search for new metals where interconnect critical dimension is 10-20 nm or below. Potential metals for sub-20-nm processes include cobalt (Co), ruthenium (Ru), tungsten (W) and molybdenum (Mo). Depending on the metal used, metal lines may be formed using a subtractive process similar to that of aluminum and tungsten, or by a single damascene process where an alternative metal is deposited followed by deposition of Cu. Thus, new dielectrics with suitable electrical and mechanical properties, which are also able to fill critical dimensions of 10-20 nm or lower are needed to realize future devices and device architechtures. In addition, the new dielectrics must withstand conditions used in subsequent process steps, which include for example high temperatures (400° C. or more), various chemicals and mechanical forces (chemical mechanical polishing).

### SUMMARY OF THE INVENTION

It is an object of the present invention to provide semiconductor devices comprising polymeric films having a dielectric constant of 2.7 or less. In particular, the present invention provides a method of manufacturing semiconductor devices comprising substrates deposited with metals selected from cobalt (Co), ruthenium (Ru), tungsten (W) and molybdenum (Mo).

In the present invention, semiconductor devices comprising low dielectric constant polymer films are provided. The films comprise a polymer obtained by polymerization of compounds having general formula I

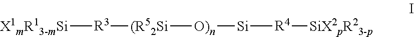

wherein
each X¹ and X² is independently selected from the group of hydrogen and organic or inorganic hydrolyzable groups;
each R¹ and R² is independently selected from the group of hydrocarbyl residues, which optionally are substituted;
each R³ and R⁴ is independently selected from the group of optionally substituted bridging linear or branched bivalent hydrocarbyl groups, such as alkylene having 1 to 6 carbon atoms and arylene having 6 to 10 carbon atoms;
each R⁵ is selected from alkyl groups having 1 to 6 carbon atoms and aryl groups having 6 to 18 carbon atoms, such as phenyl or benzyl groups, said groups optionally being substituted;
n is an integer of 1 to 5;
m is an integer of 1 to 3; and
p is an integer of 1 to 3.

In an embodiment, a polymeric film having a dielectric constant of 2.7 or less at 1 MHz is formed by
hydrolyzing a first silicon compound having the formula I

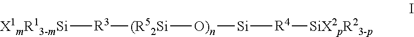

wherein X¹, X², X³, X⁴, R¹, R², R³, R⁴, R⁵, i and n, m, p have the same meaning as above,
optionally hydrolyzing at least one second compound
having the formula III

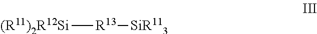

wherein
R¹¹ is a hydrolysable group, such as hydrogen, a halide, an alkoxy or an acyloxy group,
R¹² is hydrogen, an organic crosslinking group, a reactive cleaving group or a polarizability reducing organic group,
R¹³ s a bridging linear or branched bivalent hydrocarbyl group and/or having the formula IV

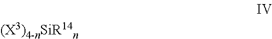

wherein X³, R¹⁴ and n have the same meaning as above
and polymerizing or copolymerizing the hydrolyzed compound(s) to produce a siloxane material.

The siloxane material is typically deposited, in the form of a thin layer, on a substrate, and the thin layer is cured to a thin film having a low dielectric constant.

More specifically, the present invention is characterized by what is stated in the independent claims.

Considerable advantages are obtained by the present invention.

Thus, in the method of manufacturing semiconductor devices according to the present invention, the disclosed siloxane materials provide high modulus and hardness and will contribute to binding together of the maze of metal interconnects and vias in particular in the final chip packaging step. As a result of good adhesive properties, the films will contribute to the forming of stable interfaces between the dielectric and contacting materials.

The siloxane materials used in the method of manufacturing semiconductor devices according to the present invention can be shaped into films of thicknesses in the range of 50 nm up to 2500 nm, such as in the range of 50 nm to 1000 nm; generally any cracking will not take place even in thick films structures.

The substrate, which is used for deposition of the siloxane material, may contain a variety of topographies. These include narrow trenches which may have high aspect ratio, meaning that the trenches exhibit a depth-to-width ratio (or aspect ratio) exceeding 2:1, for example 3:1 or higher. Thus, the materials have excellent capabilities to fill even trench widths below 20 nm or more preferably below 10 nm. In parallel, the siloxane materials exhibit excellent planarization properties. The planarization property refers to the ability of the siloxane material to even out height differences on the substrate arising from the variety of topographies present on the substrate prior to coating. The ability to planarize the substrate has significant benefits as subsequent processes to flatten the substrate surface may be eliminated or reduced. In this way, considerable benefits can be achieved in manufacturing cost and time. In addition, the films are readily processible by chemical mechanical polishing or by an etch back process in cases where the film thickness needs to be reduced or a more flat topography is needed in subsequent manufacturing process steps.

Further, the siloxane materials used in the method of manufacturing semiconductor devices according to the present invention exhibit a low coefficient of thermal expansion (CTE). A low coefficient of thermal expansion is highly beneficial to prevent bowing of the substrate in subsequent process steps. Such bowing typically takes place on substrates that contain materials with significantly variable CTEs. Preferably, the CTE of the cured siloxane material is 50 ppm/° C. or lower, more preferably, 30 ppm/° C. or lower and most preferably 20 ppm/° C. or lower.

The siloxane materials used in the method of manufacturing semiconductor devices according to the present invention are also thermally stable. Good thermal stability is required in order for the coatings to withstand multiple thermal cycles in the semiconductor manufacturing process.

Importantly, the present materials exhibit low current leakage, high breakdown voltages, and low loss-tangents.

### BRIEF DESCRIPTION OF THE DRAWINGS

FIG. 1 illustrates in a schematic fashion the various stages in the production of a semiconductor device comprising a low k dielectric, in accordance with at least some embodiments of the present invention; and

FIG. 2 illustrates in a schematic fashion the various stages of an alternative production of a semiconductor device comprising a low k dielectric consisting of a film of polysiloxane materials as disclosed herein.

### EMBODIMENTS

In the following, embodiments of the present technology are described in more detail.

Unless otherwise stated herein or clear from the context, any percentages referred to herein are expressed as percent by weight based on a total weight of the respective composition.

Unless otherwise stated, properties that have been experimentally measured or determined herein have been measured or determined at room temperature. Unless otherwise indicated, room temperature is 25° C.

Unless otherwise stated, properties that have been experimentally measured or determined herein have been measured or determined at atmospheric pressure.

It must also be noted that, as used in the specification and the appended claims, the singular forms “a,” “an” and “the” include plural referents unless otherwise specified.

As used herein, the term “about” refers to a value, which is ±5% of the stated value.

As used herein, the term “average molecular weight” refers to a weight average molecular weight (also abbreviated “Mw” or “W”).

As used herein, the molecular weight is measured by gel-permeation chromatography using polystyrene standards.

As used herein, the “coefficient of thermal expansion” is measured by stylus-based profilers that detect changes in curvature of the wafer, which results from heating the substrate having a coating.

Measurement of the “dielectric constant”, κ or εr, is achieved using a metal-insulator-semiconductor (MIS) structure on highly doped low resistivity N+ doped silicon wafers. A mercury probe (Materials Development Corporation, model 802) and precision impedance analyzer (Agilent 4294A) are used to determine the capacitance across the dielectric film which together with the mercury dot contact area and film thickness can be used to calculate the dielectric constant using equation x

$$κ = \frac{Cd}{{ε}_{0} A}$$

where κ is dielectric constant, C is capacitance, d is film thickness, ε0 is permittivity of vacuum and A is capacitor area.

“Breakdown voltage” is measured using a similar MIS structure with mercury probe (Materials Development Corporation, model 802) and semiconductor parameter analyzer (Agilent 4155B).

“Leakage current” as a function of voltage is measured during a voltage sweep from −20 V to 100 V and the breakdown voltage is found where the current suddenly spikes as the film breaks down. Breakdown voltage is given in MV/cm and is calculated by dividing the measured breakdown voltage with film thickness.

“Refractive index” (RI) is determined using a refractormeter at a wavelength of 633 nm. The RI can be calculated by, e.g. interferometry, the deviation method, or the Brewster Angle method from a polymeric film sample having a thickness of 400 nm.

“Hardness” and “elastic modulus” of films can be calculated from curve of identation by the Oliver-Pharr method.

The embodiments disclose the production of low dielectric constant polymer films which comprise siloxane polymers which exhibit —(Si—O—Si)— segments, in which the silicon atoms typically bear hydrocarbyl substituents, such as lower alkyl groups, and the use of said polymer films in a method of manufacturing semiconductor devices. Such polymeric films are obtained by polymerizing, either by homopolymerization or by copolymerization, of silane monomers.

Typically, in the present technology, silane monomers containing hydrolyzable groups are first subjected to hydrolysis and then to polymerization typically in liquid phase and at a temperature between room temperature and the boiling point of the liquid. The liquid may consist of one or more solvents, in addition to the silicon monomers and the water added for hydrolysis of the monomers. Specific, suitable solvents include acetone, ethyl methyl ketone, methanol, ethanol, isopropanol, butanol, methyl acetate, ethyl acetate, propyl acetate, butyl acetate and tetrahydrofuran. Particularly suitable solvents are alcohols, ketones, and ethers.

Controlled hydrolysis of the monomers is obtained by addition of an acid or base solution with molarity ranging from 0.0001 M to 1 M. Organic or inorganic acid can be used in the synthesis. Inorganic acids such as nitric acid, sulfuric acid, hydrocholoric acid, hydriodic acid, hydrobromic acid, hydrofluoric acid, boric acid, perchloric acid, carbonic acid and phosphoric acid can be used. Preferably, nitric acid or hydrochloric acid is used due to their low boiling point, which make purification of product simple. In other options, various organic acids are used instead of inorganic acid. Organic acids are carboxylic acid, sulfonic acid, alcohol, thiol, enol, and phenol groups. Examples are methanesulfonic acid, acetic acid, ethanesulfonic acid, toluenesulfonic acid, formic acid, and oxalic acid.

Bases used in the synthesis may similarly be inorganic or organic. Typical inorganic bases and metal hydroxides, carbonates, bicarbonates and other salts that yield an alkaline water solution. Examples of such materials are sodium hydroxide, potassium hydroxide, cesium hydroxide, calcium hydroxide, sodium carbonate, and sodium bicarbonate. Organic bases on the other hand comprise a larger group consisting of metal salts of organic acids (such as sodium acetate, potassium acetate, sodium acrylate, sodium methacrylate, sodium benzoate), linearm branched or cyclic alkylamines (such as diaminoethane, purtescine, cadaverine, triethylamine, butylamine, dibutylamine, tributylamine, piperidine) amidines and guanidines (such as 8-diazabicyclo(5.4.0)undec-7-ene, 1,1,3,3-tetramethylguanidine, 1,5,7-triazabicyclo[4.4.0]-dec-5-ene), phosphazanes (such as P₁-t-Bu, P₂-t-Bu, P₄-t-Bu), and quarternary ammonium compounds (such as tetramethylammonium hydroxide, tetraethylammonium hydroxide, tetrabutylammonium hydroxide).

The temperature of the reaction mixture during the hydrolysis and condensation process can be varied in the range from −30 to 170° C. Lower reaction temperatures provide improved control of the reaction at the cost of long reaction times, while excessively high temperatures may make the process too fast for adequate control. A reaction time of 1-48 h at a temperature of 0-100° C. is preferred. A reaction time of 2-24 h is even more preferred.

Using appropriate conditions, a partially crosslinked organosiloxane polymer in an organic solvent system is obtained, said polymer having a molecular weight of about 500 to 100,000 g/mol, preferably 800 to 50,000 g/mol, and most preferably 1000 to 10,000 measured against polystyrene standards.

In some embodiments, the solvent in which hydrolysis and polymerization is carried out, is after polymerization changed for a solvent that provides the material better coating performance and product storage properties through some form of stabilization. Such stabilizing organic solvent system is formed by an organic ether optionally in mixture with other co-solvent or co-solvents. The organic ether is a linear, branched or cyclic ether comprising generally 4 to 26 carbon atoms and optionally other functional groups, such as hydroxyl groups. Particularly suitable examples are five and six membered cyclic ethers, which optionally bear substituents on the ring, and ethers, such as (C1-20) alkanediol (C1-6) alkyl ethers. Examples of said alkanediol alkyl ethers are propylene glycol monomethyl ether, propylene glycol dimethyl ether, propylene glycol n-butyl ether, dipropylene glycol monomethyl ether, dipropylene glycol dimethyl ether, dipropyleneglycol n-butyl ether, tripropylene glycol monomethyl ether and mixtures thereof. Particularly preferred examples of the present ethers are methyl tetrahydrofurfuryl ether, tetrahydrofurfuryl alcohol, propylene glycol n-propyl ether, dipropylene glycol dimethyl ether, propylene glycol n-methyl ether, propylene glycol n-ethyl ether and mixtures thereof. The stabilizing solvent system consists of a solvent comprising of the ether of this kind alone, or of a mixture-of such ether with a typical reaction medium of the hydrolyzation or other solvents such as propylene glycol monomethyl ether acetate. The proportion of the ether is, in such a case, about 10 to 90 wt-%, in particular about 20 to 80 wt-% of the total amount of the solvent.

The solid content of the formulation, consisting of selected solvents and the hydrolysis and polymerization product, is in the range of 0.1 to 60%, preferably 0.5 to 30% and most preferably 1 to 10%.

In one particular embodiment, the polymer films in the method of manufacturing semiconductor devices are obtained by polymerization or copolymerization of compounds having the general formula I

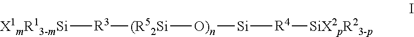

wherein
each X¹ and X² is independently selected from the group of hydrogen and organic or inorganic hydrolyzable groups;
each R¹ and R² is independently selected from the group of hydrocarbyl residues, which optionally are substituted;
each R³ and R⁴ is independently selected from the group of optionally substituted bridging linear or branched bivalent hydrocarbyl groups, such as alkylene having 1 to 6 carbon atoms and arylene having 6 to 10 carbon atoms;
each R⁵ is selected from alkyl groups having 1 to 6 carbon atoms and aryl groups having 6 to 18 carbon atoms, such as phenyl or benzyl groups, said groups optionally being substituted;
n is an integer of 1 to 5;
m is an integer of 1 to 3; and
p is an integer of 1 to 3.

According to one embodiment, in formula I,
each X¹ and X² is independently selected from the group of hydrogen and organic or inorganic hydrolyzable groups;
each R¹ and R² is independently selected from the group of hydrocarbyl residues;
each R³ and R⁴ is independently selected from the group of alkylene having 1 to 6 carbon atoms and arylene having 6 to 10 carbon atoms;
each R⁵ is selected from alkyl groups having 1 to 4 carbon atoms and phenyl groups; and
n, m and p have the same meaning as above.

In one embodiment, in formula I, each X¹ and X² is independently selected from the group of hydrogen and hydrolysable groups selected from halogen, acyloxy, alkoxy and OH groups. Typically, the halogen is selected from fluoro, chloro or bromo, and the hydrocarbyl radical of the acyl (alkanoyl) functionality of the acyloxy group is selected from alkyl groups having 1 to 6 carbon atoms.

In one embodiment, in formula I each X¹ and X² is independently selected from the group of hydrogen and an alkoxy group of formula R⁷O—, wherein R⁷ stands for an alkyl having 1 to 6 carbon atoms.

In one embodiment, in formula I each R¹ and R² is independently selected from the group of linear, branched and cyclic alkyl groups having 1 to 10 carbon atoms, aryl groups containing 1 to 5 aromatic rings, optionally containing 1 to 3 heteroatoms.

In one embodiment, each R³ and R⁴ stands for a bivalent hydrocarbyl radical, and in particular each R³ and R⁴ independently selected from the group of saturated alkylene radicals having 1 to 4, in particular 2 carbon atoms. R³ and R⁴ may also be selected from bivalent aromatic hydrocarbyl radicals, such as arylene, e.g. phenylene or naphthylene.

In formula I, hydrocarbyl groups, such as alkyl, alkylene, aryl or arylene groups, such as R¹, R², R³, R⁴ and R⁵, may optionally be substituted with 1 to 3 functional groups selected from halo, hydroxy, alkoxy, in particular C₁₋₄ alkoxy, vinyl and acetyl groups and combinations thereof.

In one embodiment, hydrocarbyl groups such as R¹, R², R³, R⁴ and R⁵, may decompose during the film curing procedure and leave behind a cross-linking group or polarizability reducing group or a combination of thereof. If group is a leaving group, still very small pore size is resulted in, i.e., typically 1.5 nm or less. However, the polymer formed according to the present technology is also compatible with traditional type porogens such as cyclodextrin, which can be used to form micro-porosity into the polymer and thus reduce the dielectric constant of the polymer.

Examples of organic crosslinking groups, reactive cleaving groups or polarizability reducing organic groups are an alkyl, alkenyl, alkynyl, aryl, polycyclic group or organic containing silicon group. The group may also be fully or partially halogenated.

In one embodiment, in formula I the symbol n stands for an integer of 1 to 5, in particular 1 to 4, such as 1, 2 or 4.

One embodiment comprises using a monomer according to general formula I that has the formula Ta

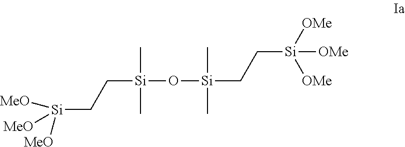

One embodiment comprises using a monomer according to general formula I that has the formula Ib

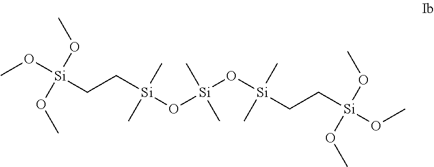

One embodiment comprises using a monomer according to general formula I that has the formula Ic

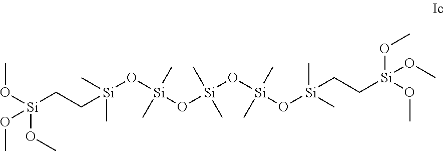

Compounds according to general formula I, as well as formulas Ia to Ic can be obtained by reaction of a difunctional siloxane compound with silane monomers comprising hydrolyzable groups and at least one reactive group, such as a vinyl group, potentially in the presence of a catalyst, such as a noble metal catalyst.

For example, the difunctional siloxane compound may have formula II

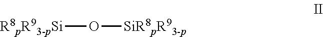

wherein
R⁸ stands for hydrogen or hydrocarbon having a vinyl group, and
R⁹ stands for an alkyl group having 1 to 6, preferably 1 to 4 carbon atoms, and
p stands for 0 or an integer 1 to 3.

In particular, R⁹ stands for methyl and p stands for 1.

In one embodiment, a polymer film is provided by homopolymerization of compounds of general formula I, such as compounds Ia, Ib or Ic, or by copolymerization of two or three compounds of formulas Ia, Ib or Ic.

In one embodiment, a polymer film is provided by copolymerization of at least one compound of formula I, such as a compound according to formula Ia, Ib or Ic, with a compound of formula III

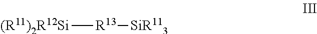

wherein
R¹¹ is a hydrolysable group, such as hydrogen, a halide, an alkoxy or an acyloxy group,
R¹² is hydrogen, an organic crosslinking group, a reactive cleaving group or a polarizability reducing organic group, and
R¹³ s a bridging linear or branched bivalent hydrocarbyl group.

R¹¹ is preferably selected from the group of halides, alkoxy groups, acyloxy groups and hydrogen, R¹² is preferably selected from alkyl groups, alkenyl groups, alkynyl and aryl groups, polycyclic group or organic containing silicon group, and R¹³ is preferably selected from linear and branched alkylene groups, alkenylene groups and alkynylene groups, bivalent alicyclic groups (polycyclic groups) and bivalent aromatic groups which all are included in the definition of a bivalent hydrocarbyl group.

“Alkenyl” as used herein includes straight-chained and branched alkenyl groups, such as vinyl and allyl groups. The term “alkynyl” as used herein includes straight-chained and branched alkynyl groups, suitably acetylene. “Aryl” means a mono-, bi-, or more cyclic aromatic carbocyclic group, substituted or non-substituted; examples of aryl are phenyl, naphthyl, or pentafluorophenyl propyl. “Polycyclic” group used herein includes for example adamantyl, dimethyl adamantyl propyl, norbornyl or norbornene. More specifically, the alkyl, alkenyl or alkynyl may be linear or branched.

The bivalent alicyclic groups may be polycyclic aliphatic groups including residues derived from ring structures having 5 to 20 carbon atoms, such as norbornene (norbornenyl) and adamantyl (adamantylene). “Arylene” stands for bivalent aryls comprising 1 to 6 rings, preferably 1 to 6, and in particular 1 to 5, fused rings, such as phenylene, naphthylene and anthracenyl.

In one embodiment, a polymer film for use in the method of manufacturing a semiconductor device as defined herein is provided by copolymerization of at least one compound of formula I, such as a compound according to formula Ia, Ib or Ic, with a compound of formula IV

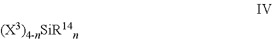

In formula IV,
X³ is hydrogen or a hydrolysable group selected from halogen, acyloxy, alkoxy and OH groups;
R¹⁴ is selected from halogen, acyloxy, alkoxy and OH groups, and alkyl groups having 1 to 6 carbon atoms, vinyl groups having from 2 to 6 carbon atoms, and aryl groups having 6 to 10 carbon atoms; and
n is an integer having the same meaning as above.

The groups acyloxy, alkoxy, alkyl, vinyl and aryl have the same meanings as above.

Specific examples of IV include, but are not limited to, tetramethoxysilane, tetrachlorosilane, tetraacetoxysilane, tetraethoxysilane, tetra-n-propoxysilane, tetraisopropoxysilane, tetra-n-butoxysilane, methyltrimethoxysilane, methyltriethoxysilane, methyltrichlorosilane, methyltriacetoxysilane, methyltripropoxysilane, methyltributoxysilane, methyltriphenoxysilane, methyltribenzyloxysilane, ethyltrimethoxysilane, ethyltriethoxysilane, vinyltrimethoxysilane, vinyltrichlorosilane, vinyltriacetoxysilane, vinyltriethoxysilane, phenyltrimethoxysilane, phenyltrichlorosilane, phenyltriacetoxysilane, phenyltriethoxysilane, γ-chloropropyltrimethoxysilane, γ-chloropropyltriethoxysilane, γ-chloropropyltriacetoxysilane, 3,3,3-trifluoropropyltrimethoxysilane, γ-methacryloxypropyltrimethoxysilane, γ-mercaptopropyltrimethoxysilane, γ-mercaptopropyltriethoxysilane, β-cyanoethyltriethoxysilane, chloromethyltrimethoxysilane, chloromethyltriethoxysilane, dimethyldimethoxysilane, phenylmethyldimethoxysilane, dimethyldiethoxysilane, phenylmethyldiethoxysilane, γ-chloropropylmethyldimethoxysilane, γ-chloropropylmethyldiethoxysilane, dimethyldiacetoxysilane, γ-methacryloxypropylmethyldimethoxysilane, γ-methacryloxypropylmethyldiethoxysilane, γ-mercaptopropylmethyldimethoxysilane, γ-mercaptomethyldiethoxysilane, methylvinyldimethoxysilane, methylvinyldiethoxysilane, glycidoxymethyltrimethoxysilane, glycidoxymethyltriethoxysilane, α-glycidoxyethyltrimethoxysilane, α-glycidoxyethyltriethoxysilane, β-glycidoxyethyltrimethoxysilane, β-glycidoxyethyltriethoxysilane, α-glycidoxypropyltrimethoxysilane, α-glycidoxypropyltriethoxysilane, β-glycidoxypropyltrimethoxysilane, β-glycidoxypropyltriethoxysilane, γ-glycidoxypropyltrimethoxysilane, γ-glycidoxypropyltriethoxysilane, γ-glycidoxypropyltripropoxysilane, γ-glycidoxypropyltributoxysilane, γ-glycidoxypropyltriphenoxysilane, α-glycidoxybutyltrimethoxysilane, α-glycidoxybutyltriethoxysilane, β-glycidoxybutyltriethoxysilane, γ-glycidoxybutyltrimethoxysilane, γ-glycidoxybutyltriethoxysilane, δ-glycidoxybutyltrimethoxysilane, δ-glycidoxybutyltriethoxysilane, (3,4-epoxycyclohexyl)methyltrimethoxysilane, (3,4-epoxycyclohexyl)methyltriethoxysilane, β-(3,4-epoxycyclohexyl)ethyltrimethoxysilane, β-(3,4-epoxycyclohexyl)ethyltriethoxysilane, β-(3,4-epoxycyclohexyl)ethyltripropoxysilane, β-(3,4-epoxycyclohexyl)ethyltributoxysilane, β-(3,4-epoxycyclohexyl)ethyltriphenoxysilane, γ-(3,4-epoxycyclohexyl)propyltrimethoxysilane, γ-(3,4-epoxycyclohexyl)propyltriethoxysilane, 6-(3,4-epoxycyclohexyl)butyltrimethoxysilane, 6-(3,4-epoxycyclohexyl)butyltriethoxysilane, glycidoxymethylmethyldimethoxysilane, glycidoxymethylmethyldiethoxysilane, α-glycidoxyethylmethyldimethoxysilane, α-glycidoxyethylmethyldiethoxysilane, β-glycidoxyethylmethyldimethoxysilane, β-glycidoxyethylethyldimethoxysilane, α-glycidoxypropylmethyldimethoxysilane, α-glycidoxypropylmethyldiethoxysilane, β-glycidoxypropylmethyldimethoxysilane, β-glycidoxypropylethyldimethoxysilane, γ-glycidoxypropylmethyldimethoxysilane, γ-glycidoxypropylmethyldiethoxysilane, γ-glycidoxypropylmethyldipropoxysilane, γ-glycidoxypropylmethyldibutoxysilane, γ-glycidoxypropylmethyldiphenoxysilane, γ-glycidoxypropylethyldimethoxysilane, γ-glycidoxypropylethyldiethoxysilane, γ-glycidoxypropylvinyldimethoxysilane, γ-glycidoxypropylvinyldiethoxysilane, and phenylsulfonylaminopropyltriethoxysilane.

As used herein, “alkoxy” and “acyloxy” groups typically have 1 to 6 carbon atoms.

As used herein, “halogen” has the conventional meaning and stands in particular for chloro, fluoro or bromo.

As used herein, “halide” has the conventional meaning and stands for a halogen compound.

In one embodiment, a polymer film is provided by copolymerization of a compound of formula I with compounds of formulas III and IV, i.e. with a mixture of compounds of formulas III and IV.

In one embodiment, wherein copolymers are produced, the molar ratio between compounds according to formula I and of formula III is in the range of 10:90 to 90:10. For example, the molar ratio between compounds according to formula I and of formula III is 20:80 to 80:20, in particular 40:60 to 60:40.

In one embodiment, wherein copolymers are produced, the molar ratio between compounds according to formula I and of formula IV is in the range of 10:90 to 90:10. For example, the molar ratio between compounds according to formula I and of formula IV is 20:80 to 80:20, in particular 40:60 to 60:40.

In one embodiment, wherein copolymers are produced, the molar ratio between compounds according to formula I, on one hand, and of compounds of formulas III and IV, on the other, is in the range of 10:90 to 90:10. For example, the molar ratio between compounds according to formula I and of formulas III and IV is 20:80 to 80:20, in particular 40:60 to 60:40.

Typically, the organic content of the polymer is in the range of 20 to 60 wt %. Generally, an organic content of less than 40 wt % is preferred.

In one embodiment, a polymeric film having a dielectric constant of 2.7 or less (e.g. 2.5 or less) at 1 MHz for use in a method for manufacturing a semiconductor device according to the invention is produced by a method comprising the steps of
hydrolyzing a first silicon compound having the formula I

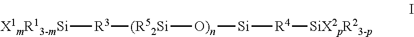

wherein X¹, X², X³, X⁴, R¹, R², R³, R⁴, R⁵, I and n, m, p have the same meaning as above;
optionally hydrolyzing at least one second silicon compound having the formula III

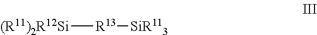

wherein
R¹¹ is a hydrolysable group, such as hydrogen, a halide, an alkoxy or an acyloxy group,
R¹² is hydrogen, an organic crosslinking group, a reactive cleaving group or a polarizability reducing organic group, and
R¹³ s a bridging linear or branched bivalent hydrocarbyl group;
and/or having the formula IV

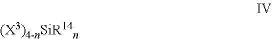

wherein X³, R¹⁴ and n have the same meaning as above, and
polymerizing the hydrolyzed compound(s) to produce a polymerized siloxane material; and
shaping the polymerized material into a layer which is cured into a film.

In one embodiment, the siloxane material obtained by homo- or optionally copolymerization of compounds according to formulas I and, optionally, III and/or IV, is deposited in the form of a layer on a substrate and the deposited material is then cured into a film.

The layer has typically a thickness of less than 2 gm, in particular less than 1 μm, in particular less than about 500 nm.

The layers are cured into polymer films generally having a thickness of less than 1 μm, in particular less than about 500 nm, typically of about 50 to 350 nm.

The present films have good optical properties. Thus, a polymer film may have a refractive index (RI) greater than 1.4 determined at a wavelength of 633 nm.

Surprisingly it has been found that by using monomers of formula I in polymeric films, consisting of or comprising such monomers, excellent electric properties are obtained in semiconductor devices, which comprise substrates deposited with metals selected from cobalt (Co), ruthenium (Ru), tungsten (W) and molybdenum (Mo).

Further, it has also been found that by incorporating a short linear segment (n having a value of 1 to 5) a material can be obtained which exhibits a combination of low thermal expansion and modest elasticity/softness or significant hardness.

In one embodiment, the dielectric constant at 1 MHz of the film is 2.7 or less, such as 2.5 or less. In further embodiments, the dielectric constant of the polymer after curing is 2.45 or less, preferably 2.30 or less.

In one embodiment, the cured polymeric films have an electric breakthrough voltage of 3.5 MV/cm or more, such as 3.55 MV/cm or more, for example 3.6 MV/cm or more.

In one embodiment, the cured polymeric films exhibit a coefficient of thermal expansion lower than 10 ppm/° C., such as lower than 9.5 ppm/° C. or lower than 9 ppm/° C.

In one embodiment, the cured polymeric films exhibit an elastic modulus of 6.3 GPa or more, such as 6.5 GPa or more, for example 6.7 GPa or more.

In one embodiment, the cured polymeric films exhibit a hardness of 1.5 GPa or more, such as 1.6 GPa or more, for example 1.7 GPa or more.

Effect on mechanical properties is dominated by length of bridging group in formula I, as increasing n in formula I decreases both elastic modulus and hardness. Surprisingly, it has been found that using monomers of formula I having n≤2, films prepared by either homo- or copolymerization experience hardness comparable to films prepared from monomers of formula III and/or IV.

In one embodiment, by using monomers of formula I in amounts of at least 10 mol % of the total amount of silane monomers, the electric properties, such as electric breakthrough voltage, of polysiloxanes films manufactured from silane monomers of formula II can be significantly improved.

In one embodiment, by using monomer of formula I in amounts of at least 10 mol % of the total amount of silane monomers, significant reduction of dielectric constant can be observed compared to films made of only formula III and/or IV monomers. Surprisingly, significant reduction of dielectric constant is detected for both homo- and copolymers including formula I monomers.

In one embodiment, by using monomer of formula I in amounts of at least 10 mol % of the total amount of silane monomers, significant reduction in film shrinkage can be observed compared to films made of only formula III and/or IV monomers. Surprisingly, significant reduction of shrinkage is detected for both homo- and copolymers including formula I monomers. Small shrinkage is highly beneficial to prevent bowing of the substrate in subsequent process steps.

The formulation can be optimized with various type of surfactants, such as silicone or fluoro surfactants, as they lower surface tension of the silanol-containing polysiloxane formulation coating. The use of such surfactants may improve coating quality if needed. The amount of surfactant is in a range of 0.001% to 20% by mass compared to silanol-containing organosiloxane amount, preferably 0.005 to 10% and most preferably 0.01 to 5% or 0.05 to 2.5%.

The tormulation can be optimized with various types of photo or thermally labile catalysts or compounds added to formulation mixture to enhance crosslinking of the organosiloxane films. The amount of thermos- or photo-labile compounds in the formulation is in the range of 0.05 to 20% by mass compared to silanol-containing organosiloxane amount, preferably 0.1 to 10% and most preferably 0.5 to 5% or 0.5 to 3%, corresponding to the solid content of the polymer.

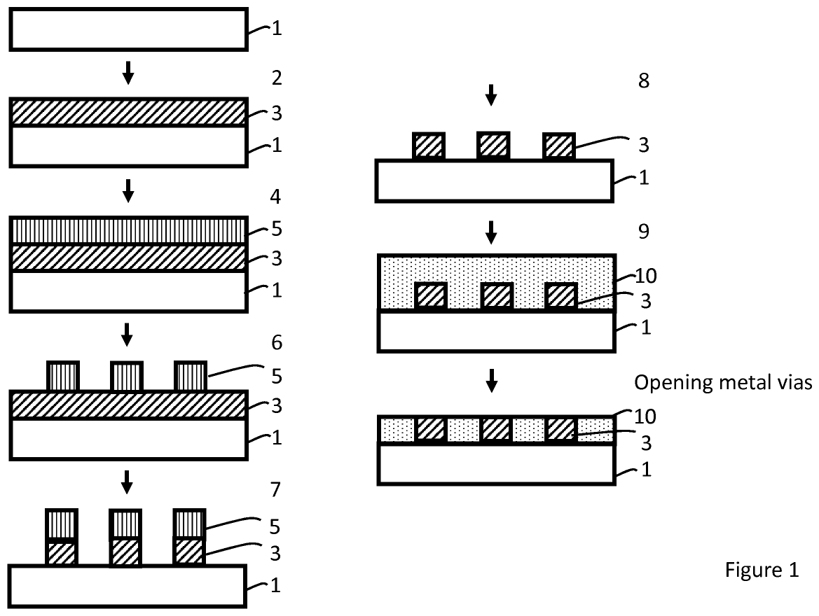

FIG. 1 illustrates the various stages in the production of a semiconductor device according to the present technology, comprising a low k dielectric consisting of a film of a polysiloxane as disclosed herein.

As will appear, first a substrate 1 is provided. Such a substrate may for example comprise a silicon wafer. The substrate is subjected to metal deposition 2 in a second stage. The metal layer consists of an electrically conductive metal 3. Conventionally copper has been used for such purposes, but for patterned devices with spaces having diameters of 1 to 50 nm, such as 1 to 20 nm or even 5 to 15 nm, the metals are selected from cobalt, molybdenum, tungsten, ruthenium or some other suitable metal, preferably from cobalt (Co), molybdenum (Mo) and ruthenium (Ru).

The substrate 1 with the metal layer 3 is subjected to patterning by known steps in lithograpy including photoresist coating 4 (and required photoresist underlayers) using a suitable photoresist coating material 5, such as a material suitable for patterning with electromagnetic radiation in the UV range or even the Extreme UV range (EUV).

After an exposure and development step 6, pattern transfer by etching 7 of the metal layer 3 is carried out. Thereafter, the remaining photoresist and photoresist underlayers are stripped off 8 to leave the substrate with a patterned metal layer 3.

In the two following steps, a dielectric coating 10 is applied 9 onto the patterned metal layer 3 and on the substrate 1 to fill the spaces between the metal patterns. Finally, the metal 10, separated by the dielectric, are opened 11 by etch-back for example using gas or chemical mechanical polishing (CMP).

As a result, a semiconductor device is provided comprising a dielectric formed by a polymer film according to the present technology.

In summary, a method of manufacturing a semiconductor device according to the present technology comprises or consists of the following steps:
providing a substrate;
depositing a metal layer comprising metals selected from from cobalt (Co), molybdenum (Mo), tungsten (W) and ruthenium (Ru) on the substrate;
depositing photoresist and auxiliary underlayers on top of the metal;
exposing the said photoresist stack to light or an electron beam through a mask to form a desired pattern;
developing the soluble parts of the photoresist and transferring the formed pattern to the metal layer by selective etch processes;
removing residual parts of the photoresist stack;
depositing and curing a low-k dielectric film according to any of the present embodiments; and
removing excess of deposited low-k dielectric film by an etch back or chemical mechanical polishing process.

Preferably, the metals are selected from cobalt (Co), molybdenum (Mo) and ruthenium (Ru).

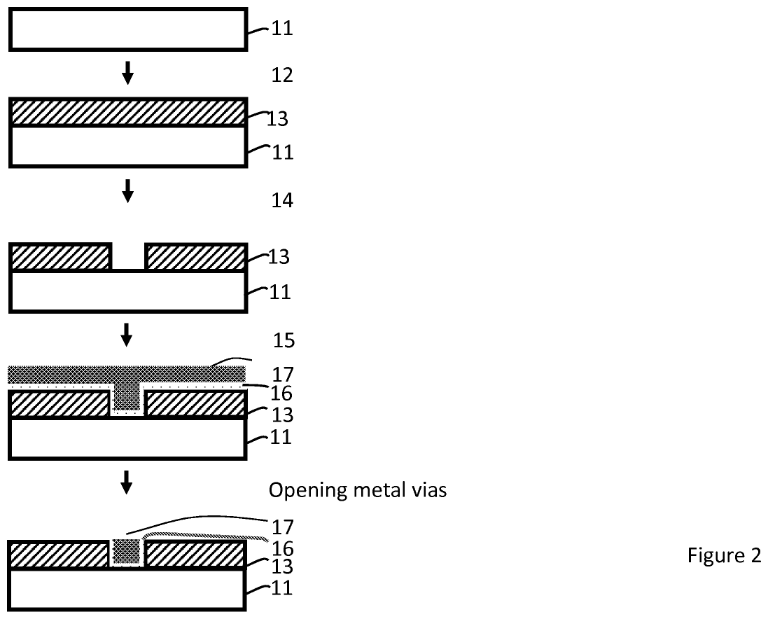

FIG. 2 illustrates the various stages of an alternative production of a semiconductor device comprising a low k dielectric consisting of a film of a polysiloxane materials as disclosed herein according to the present technology.

As will appear, first a substrate 11 is provided. Such a substrate may for example comprise a silicon wafer. The substrate is subjected to dielectric coating in a second stage 12 to provide a layer of a low k dielectric 13 on top of (at least one surface of) the substrate 11. The thus coated substrate is then subjected, in a second step, to etching to remove predetermined parts of the dielectric and, thus, to pattern the surface. In a third stage a barrier material 16 and an overlapping layer of a metal 17 are deposited upon the surface. The metal layer may for example comprise a conductive layer, such as copper.

As can be seen the barrier material 16 and metal 17 typically cover both the etched parts and the non-etched parts of the surface. In a final, fourth stage 18 the multilayered structure is thence subjected to metal via opening, e.g. by chemical mechanical polishing. As a result, a semiconductor device is obtained, comprising a low k dielectric with embedded metal vias.

The following non-limiting examples illustrate further embodiments.

### EXAMPLES

### Monomers

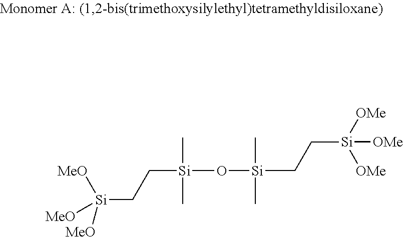 [SMILES: CO[Si](CC[Si](C)(C)O[Si](C)(C)CC[Si](OC)(OC)OC)(OC)OC]

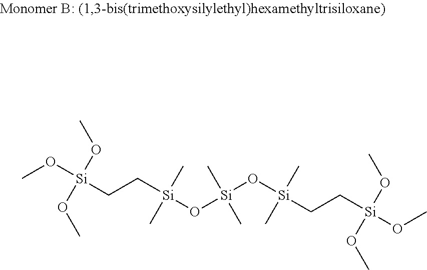

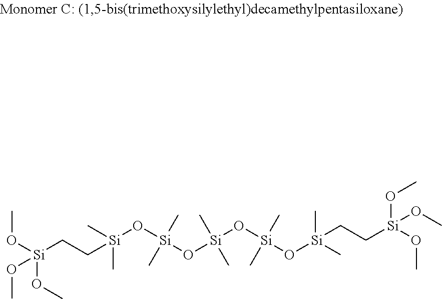 [SMILES: CO[Si](CC[Si](C)(C)O[Si](C)(C)O[Si](C)(C)O[Si](C)(C)O[Si](C)(C)CC[Si](OC)(OC)OC)(OC)OC]

### Synthesis of Monomer A

Monomer A was prepared by adding vinyltrimethoxysilane (VinTMOS, 971.9 g, 6.56 mol), platinum catalyst (1 g), and acetic acid (0.2 g) to a 3 L flask. The solution was mixed thoroughly at 40° C. and tetramethyl disiloxane (TMDS, 400 g, 2.98 mol) was added to the solution. After the addition of TMDS, the reaction mixture was kept at room temperature overnight. After completion of reaction, distillation was carried out under reduced pressure. The amount of product obtained was 920 g (yield 71%, GC-MS purity 99%).

### Synthesis of Monomer B

Monomer B was prepared by adding VinTMOS (39 g, 0.26 mol), platinum catalyst (100 mg), and 2 drops of acetic acid to a flask. Hexamethyl trisiloxane (HMTS, 0.12 mol) was added slowly to the solution, which was stirred overnight. Monomer was purified by distillation under reduced pressure. The amount of the product obtained was 44 g (yield 76%, GC-MS purity 99%).

### Synthesis of Monomer C

Monomer C was prepared by adding hexamethylcyclotrisiloxane (D3, 7 g, 0.34 mol), TMDS (113 g, 0.84 mol), and toluene (20 g). A flask was kept under ice cold conditions and purged with the nitrogen gas for five minutes. Triflic acid (300 mg) was added to solution. After five minutes, hexamethyldisilazane (6 ml) was added to the solution as a quencher. Stirring was continued in ice cold condition for ten minutes. Intermediate product was purified under reduced pressure. The amount of the intermediate product obtained was 81 g (yield 67%, GC-MS purity 99%).

In a 500 mL flask VinTMOS (46 g, 0.31 mol), a few drops of acetic acid and platinum catalyst (100 mg) were added. The flask was placed in oil bath (50° C.) and the obtained intermediate product (50 g) was added to a solution. The solution was stirred overnight. Monomer thus obtained was purified by distillation under reduced pressure. The amount of product obtained was 56 g (yield 61%, GC-MS purity 97.5%.

### Polymer preparation

Example 1. A homopolymer of the obtained Monomer A was prepared in a 250 ml round bottom flask. The monomer A (5.6 g, 0.03 mol), acetone (37 g) and 0.01 M HCl (2.2 g) were added to flask. The reaction mixture was refluxed for 30 minutes and cooled down to room temperature after that. PGMEA (56 g) was added to the reaction mixture. Acetone and hydrolysis products were removed under reduced pressure yielding a formulation having a solid content of 23%. The obtained polymer solution was filtered with a 0.2 μm PTFE filter and characterized by gel permeation chromatography (GPC). Weight average and number average molecular weights were determined to be 1716/968, respectively. An 8% formulation of the polymer was prepared with PGMEA and spin-coated on silicon wafer for refractive index and electrical properties measurements.

Example 2. A co-polymer of the obtained monomer A and 1-trimethoxysilyl-2-methyldimethoxysilyl-ethane was prepared in a 100 ml round bottom flask. The monomer A (8.6 g, 0.02 mol), 1-trimethoxysilyl-2-dimethoxymethyl-ethylene (5.1 g, 0.02 mol), acetone (41 g) and 0.01 M HCl (4.0 g) were added to flask. The reaction mixture was refluxed for 30 minutes and cooled down to room temperature after that. PGMEA (55 g) was added to the reaction mixture. Acetone and hydrolysis products were removed under reduced pressure yielding a formulation having a solid content of 15%. The obtained polymer solution was filtered with 0.2 μm PTFE filter and characterized by gel permeation chromatography (GPC). Weight average and number average molecular weights were determined to be 1823/821, respectively. An 8% formulation of the polymer was prepared with PGMEA and spin-coated on silicon wafer for refractive index and electrical properties measurements.

Example 3. A copolymer of the obtained monomer A and 1-trimethoxysilyl-2-methyldimethoxysilyl-ethane was prepared in a 100 ml round bottom flask. The monomer A (4.3 g, 0.01 mol), 1-trimethoxysilyl-2-dimethoxymethyl-ethylene (22.9 g, 0.09 mol), acetone (82 g) and 0.01M HCl (9.2 g) were added to flask. The reaction mixture was refluxed for 30 minutes and cooled down to room temperature after that. MIBK (190 g) was added to the reaction mixture. Acetone and hydrolysis products were removed under reduced pressure yielding a formulation having a solid content of 19%. The obtained polymer solution was filtered with 0.2 μm PTFE filter and characterized by gel permeation chromatography (GPC). Weight average and number average molecular weights were determined to be 1833/922, respectively. An 8% formulation of the polymer was prepared with PGMEA and spin-coated on silicon wafer for refractive index and electrical properties measurements.

Example 4.A terpolymer of the obtained monomer A, methyltriethoxysilane (MTEOS) and tetraethyl orthosilicate (TEOS) was prepared in a 100 ml round bottom flask. The precursor A (8.6 g, 0.02 mol), MTEOS (1.78 g, 0.01 mol), TEOS (2.08 g, 0.01 mol), acetone (26 g) and 0.01M HCl (3.4 g) were added to flask. The reaction mixture was refluxed for 30 minutes and cooled down to room temperature after that. PGMEA (33 g) was added to the reaction mixture. Acetone and hydrolysis products were removed under reduced pressure yielding a formulation having a solid content of 12%. The obtained polymer solution was filtered with 0.2 um PTFE filter and characterized by gel permeation chromatography (GPC). Weight average and number average molecular weights were determined to be 1860/893, respectively. An 8% formulation of the polymer was prepared with PGMEA and spin-coated on silicon wafer for refractive index and electrical properties measurements.

Example 5. A terpolymer of the obtained monomer A, methyltriethoxysilane (MTEOS) and tetraethyl orthosilicate (TEOS) was prepared in a 100 ml round bottom flask. The precursor A (8.6 g, 0.02 mol), MTEOS (4.3 g, 0.02 mol), TEOS (4.87 g, 0.02 mol), acetone (26 g) and 0.01M HCl (5.1 g) were added to flask. The reaction mixture was refluxed for 30 minutes and cooled down to room temperature after that. PGMEA (63 g) was added to the reaction mixture. Acetone and hydrolysis products were removed under reduced pressure yielding a formulation having a solid content of 19%. The obtained polymer solution was filtered with 0.2 μm PTFE filter and characterized by gel permeation chromatography (GPC). Weight average and number average molecular weights were determined to be 2532/1200, respectively. The 8% formulation of the polymer was prepared with PGMEA and spin-coated on silicon wafer for refractive index and electrical properties measurements.

Example 6. A homopolymer of the obtained precursor Monomer B was prepared in 100 ml round bottom flask. The monomer B (10.1 g, 0.02 mol), acetone (30 g) and 0.01M HCl (2.2 g) were added to flask. The reaction mixture was refluxed for 30 minutes and cooled down to room temperature after that. PGMEA (100 g) was added to the reaction mixture. Acetone and hydrolysis products were removed under reduced pressure yielding a formulation having a solid content of 36%. The obtained polymer solution was filtered with 0.2 μm PTFE filter and characterized by gel permeation chromatography (GPC). Weight average and number average molecular weights were determined to be 1744/652, respectively. An 8% formulation of the polymer was prepared with PGMEA, MIBK and surfactant and spin-coated on silicon wafer for refractive index and electrical properties measurements.

Example 7. A co-polymer of the obtained monomer B and 1-trimethoxysilyl-2-methyldimethoxysilyl-ethane was prepared in a 100 ml round bottom flask. The monomer B (10.1 g, 0.02 mol), 1-trimethoxysilyl-2-dimethoxymethyl-ethylene (5.1 g, 0.02 mol), acetone (46 g) and 0.01M HCl (4.0 g) were added to flask. The reaction mixture was refluxed for 30 minutes and cooled down to room temperature after that. PGMEA (100 g) was added to the reaction mixture. Acetone and hydrolysis products were removed under reduced pressure yielding a formulation having a solid content of 40%. The obtained polymer solution was filtered with 0.2 μm PTFE filter and characterized by gel permeation chromatography (GPC). Weight average and number average molecular weights were determined to be 1644/602, respectively. A 7% formulation of the polymer was prepared with PGMEA and MIBK and spin-coated on silicon wafer for refractive index and electrical properties measurements.

Example 8. A co-polymer of the obtained precursor Monomer C and 1-trimethoxysilyl-2-methyldimethoxysilyl-ethane was prepared in 100 ml round bottom flask. The Monomer C (6.5 g, 0.01 mol), 1-trimethoxysilyl-2-methyldimethoxysilyl-ethane (1.1 g, 0.004 mol), acetone (23 g) and 0.01M HCl (1.6 g) were added to flask. The reaction mixture was refluxed for 30 minutes and cooled down to room temperature after that. MIBK (100 g) was added to the reaction mixture. Acetone and hydrolysis products were removed under reduced pressure yielding a formulation having a solid content of 30%. The obtained polymer solution was filtered with 0.2 μm PTFE filter and characterized by gel permeation chromatography (GPC). Weight average and number average molecular weights were determined to be 3287/1547, respectively. An 8% formulation of the polymer was prepared with MIBK and spin-coated on silicon wafer for refractive index and electrical properties measurements.

Example 9. A co-polymer of the obtained precursor Monomer C and 1-trimethoxysilyl-2-methyldimethoxysilyl-ethane was prepared in 100 ml round bottom flask. The Monomer C (6.5 g, 0.01 mol), 1-trimethoxysilyl-2-methyldimethoxysilyl-ethane (2.5 g, 0.01 mol), acetone (27 g) and 0.01M HCl (2.2 g) were added to flask. The reaction mixture was refluxed for 30 minutes and cooled down to room temperature after that. MIBK (100 g) was added to the reaction mixture. Acetone and hydrolysis products were removed under reduced pressure yielding a formulation having a solid content of 21%. Obtained polymer solution was filtered with 0.2 μm PTFE filter and characterized by gel permeation chromatography (GPC). Weight average and number average molecular weights were determined to be 2758/1324, respectively. An 8% formulation of the polymer was prepared with MIBK and spin-coated on silicon wafer for refractive index and electrical properties measurements.

Example 10. A terpolymer of the obtained precursor Monomer C, TEOS and MTEOS was prepared in 100 ml round bottom flask. The Monomer C (6.5 g, 0.01 mol), MTEOS (0.89 g, 0.01 mol), TEOS (1.0 g, 0.005 mol), acetone (25 g) and 0.01 M HCl (1.9 g) were added to flask. The reaction mixture was refluxed for 30 minutes and cooled down to room temperature after that. MIBK (100 g) was added to the reaction mixture. Acetone and hydrolysis products were removed under reduced pressure yielding a formulation having a solid content of 12%. The obtained polymer solution was filtered with 0.2 μm PTFE filter and characterized by gel permeation chromatography (GPC). Weight average and number average molecular weights were determined to be 2980/1513, respectively. An 8% formulation of the polymer was prepared with MIBK and spin-coated on silicon wafer for refractive index and electrical properties measurements.

### Comparative Examples

Comparative Example 1. A co-polymer of tetraethyl orthosilicate (TEOS) and methyltriethoxysilane (MTEOS) was prepared in a 100 ml round bottom flask. TEOS (83 g, 0.4 mol), MTEOS (71 g, 0.4 mol), acetone (155 g) and 0.01M HCl (61 g) were added to flask. The reaction mixture was refluxed for 18 hours and cooled down to room temperature after that. PGEE (500 g) was added to the reaction mixture. Acetone and hydrolysis products were removed under reduced pressure yielding a formulation having a solid content of 21%. PGMEA was added to formulation and obtained polymer solution was filtered with a 0.2 μm PTFE filter and characterized by gel permeation chromatography (GPC). Weight average and number average molecular weights were determined to be 2061/1293, respectively. A 6% formulation of the polymer was prepared with PGMEA and spin-coated on silicon wafer for refractive index and electrical properties measurements.

Comparative Example 2. A polymer consisting of TEOS, MTEOS and triethoxysilane (HTEOS) was prepared in a 4 L flask. TEOS (57 g, 0.27 mol), MTEOS (98 g, 0.55 mol), HTEOS (45 g, 0.27 mol), isopropyl alcohol (301 g) and 0.01M HCl (97 g) were added to flask. The reaction mixture was refluxed for 30 minutes and cooled down to room temperature after that. PGMEA (900 g) was added to the reaction mixture. Acetone and hydrolysis products were removed under reduced pressure yielding a formulation having a solid content of 40%. Obtained polymer solution was filtered with 0.2 μm PTFE filter and characterized by gel permeation chromatography (GPC). Weight average and number average molecular weights were determined to be 1624/900, respectively. The 5% formulation of polymer was prepared with PGMEA and PGEE, and spin-coated on silicon wafer for refractive index and electrical properties measurements.

Comparative Example 3. A homopolymer of 1-trimethoxysilyl-2-methyldimethoxysilyl-ethane was prepared in a 4 L flask. 1-trimethoxysilyl-2-methyldimethoxysilyl-ethane (200 g, 0.78 mol), methanol (402 g) and 0.01M HCl (71 g) were added to flask. The reaction mixture was refluxed for 30 minutes and cooled down to room temperature after that. PGME (870 g) was added to the reaction mixture. Acetone and hydrolysis products were removed under reduced pressure yielding a formulation having a solid content of 25%. The obtained polymer solution was filtered with a 0.2 μm PTFE filter and characterized by gel permeation chromatography (GPC). Weight average and number average molecular weights were determined to be 1313/629, respectively. The 5% formulation of polymer was prepared with PGMEA and PGEE, and spin-coated on silicon wafer for refractive index and electrical properties measurements.

Polymers described in Examples 1 to 10 and comparative examples 1 to 3 were analysed for their properties.

The measurements of the dielectric constant were done at 100 kHz frequency on films with target thickness of 340 nm±20 nm. The wafers were prebaked prior to measurement at 150° C./5 min to remove any accumulated moisture and the measurement was carried out at room temperature.

The measurements of the leakage current were done on films with a target thickness of 100 nm±20 nm. The wafers were prebaked prior to measurement at 150° C./5 min to remove any accumulated moisture and the measurement was carried out at room temperature.

The measurements of Molecular weight was collected with gel permeation chromotagraphy against polystyrene standards with known molecular weights using a Waters HPLC equipment including Waters 1515 isocratic HPLC pump, Waters 2414 refractive index detector, Water column block heater module, Waters 717plus Autosampler, Waters valve selector, Waters switching valve, Waters In-line Degasser AF and Waters Temperature control module II. It was equipped with Styragel HR columns (guard column, HR1, HR3, HR4) connected in series. Flow rate of THF eluent was 1.0 ml/min.

Film thickness measurement was carried out using J. A. Woollam M2000D-ESM-200AXY spectroscopic ellipsometer.

Coefficient of thermal expansion (CTE) was determined using KLA-Tencor FLX-2320 thin film stress measurement system which uses dual-wavelength laser to determine changes in wafer radius of curvature pre and post film deposition. By depositing the same film on two dissimilar substrates with known thermal expansion properties and performing a stress vs. temperature measurement, the CTE of the film can be calculated. Stress vs. temperature was measured at a temperature between 21 and 200° C. and substrates of silicon and GaAs were used. Temperature was increased 2.5° C./min during ramp up phase and decreased 1.5° C./min during cooling phase.

Mechanical properties were measured by nanoindentation with Nanovea mechanical tester PB1000 with target load of 0.05 mN, loading and unloading rate of 0.02 V/min, approach speed 0.5 μm/min and contact load of 0.006 mN, and using Berkovich indenter and diamond as material. Hardness and elastic modulus were directly calculated from the curve of identation by the Oliver-Pharr method.

Table 1 gives a compilation of the average molecular weight (Mw) of the polymer, its refractive index (RI), electric breakthrough voltage (EBD) and shrinkage for the above 10 polymers according to the present technology and Table 2 gives a compilation of the average molecular weight (Mw) of the polymer, its refractive index (RI), electric breakthrough voltage (EBD) and shrinkage for three reference samples.

TABLE 1

| Polymer # | Mw (g/mol) | n at 633 nm | EBD (MV/cm) | Shrinkage (%) |
|---|---|---|---|---|
| 1 | 1716 | 1.434 | 4.5 | 0.6 |
| 2 | 1823 | 1.423 | 4.7 | 0.8 |
| 3 | 1833 | 1.426 | 3.9 | 0.1 |
| 4 | 1860 | 1.418 | 4.5 | −0.9 |
| 5 | 2532 | 1.408 | 4.5 | −0.2 |
| 6 | 1744 | 1.445 | 3.6 | 4.8 |
| 7 | 1649 | 1.442 | 4.0 | −0.7 |
| 8 | 3287 | 1.440 | 4.1 | 10.2 |
| 9 | 2758 | 1.432 | 4.0 | 6.1 |
| 10 | 2980 | 1.432 | 3.7 | 7.6 |

TABLE 2
Comparative examples

| Polymer # | Mw (g/mol) | n at 633 nm | EBD (MV/cm) | Shrinkage (%) |
|---|---|---|---|---|
| C1 | 2061 | 1.373 | 3.2 | 3.6 |
| C2 | 1877 | 1.376 | 3.6 | 2.0 |
| C3 | 1313 | 1.420 | 3.6 | 1.8 |

As will appear from the above, by means of the present materials a combination of high electric breakthrough voltage and excellent refractive index can be obtained.

Table 3 provides a compilation of dielectric constants and refractive indeces.

TABLE 3
Dielectric constants

| Polymer | n at 633 nm | k |
|---|---|---|
| Comparative example 2 | 1.373 | 2.9 |
| Example 1 | 1.434 | 2.5 |
| Example 2 | 1.423 | 2.4 |
| Example 10 | 1.432 | 2.7 |

As is demonstrated above, by means of the present materials a combination of low dielectric constant and excellent refractive index can be obtained. It is notable that reduction in dielectric constant is not achieved by increasing porosity of the film, as refractive indeces well above 1.4 are obtained.

Table 4 provides compilation of mechanical properties.

TABLE 4
Mechanical properties

| | Elastic modulus | Hardness | Hardness |
|---|---|---|---|
| Polymer | (GPa) | (GPa) | (HV) |
| Comparative example 2 | 12.3 | 2.4 | 228 |
| Example 1 | 6.8 | 2.2 | 205 |
| Example 2 | 6.8 | 1.6 | 149 |
| Example 4 | 6.3 | 1.5 | 144 |

Table 5 provides a compilation of coefficients of thermal expansion (CTE).

TABLE 5
Coefficients of thermal expansion

| Polymer | CTE |
|---|---|
| Example 1 | 6.4 |
| Example 6 | 6.0 |

As will be understood from the preceding description of the present invention and the illustrative experimental examples, the present invention may also be described by reference to the following embodiments:

1. A low dielectric constant polymer film comprising a polymer obtained by polymerization of compounds having the general formula I

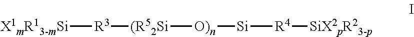

wherein
each X¹ and X² is independently selected from the group of hydrogen and organic or inorganic hydrolysable groups;
each R¹ and R² is independently selected from the group of hydrocarbyl residues, which optionally are substituted;
each R³ and R⁴ is independently selected from the group of optionally substituted bridging linear or branched bivalent hydrocarbyl groups, such as alkylene having 1 to 6 carbon atoms and arylene having 6 to 10 carbon atoms;
each R⁵ is selected from alkyl groups having 1 to 6 carbon atoms and aryl groups having 6 to 18 carbon atoms, such as phenyl or benzyl groups, said groups optionally being substituted;
n is an integer of 1 to 5;
m is an integer of 1 to 3; and
p is an integer of 1 to 3.

2. The polymer film according to embodiment 1, wherein each X¹ and X² is independently selected from the group of hydrogen and hydrolysable group selected from halogen, acyloxy, alkoxy and OH groups.

3. The polymer film according to embodiment 1 or 2, wherein each X¹ and X² is independently selected from the group of hydrogen and R⁷O—, wherein R⁷ stands for an alkyl having 1 to 6 carbon atoms.

4. The polymer film according to any of the preceding embodiments, wherein each R¹ and R² is independently selected from the group of linear, branched and cyclic alkyl groups having 1 to 10 carbon atoms, aryl groups containing 1 to 5 aromatic rings, optionally containing 1 to 3 heteroatoms, each optionally being substituted with 1 to 3 functional groups selected from halo, hydroxy, alkoxy, vinyl and acetyl groups.

5. The polymer film according to any of the preceding embodiments, wherein each R³ and R⁴ is independently selected from alkylene having 1 to 4, in particular 2 carbon atoms.

6. The polymer film according to any of the preceding embodiments, wherein n stands for an integer of 1 to 5, in particular 1 to 4, such as 1, 2 or 4.

7. The polymer film according to any of the preceding embodiments, wherein, in formula I, each X¹ and X² is independently selected from the group of hydrogen and organic or inorganic hydrolysable groups;
each R¹ and R² is independently selected from the group of hydrocarbyl residues; each R³ and R⁴ is independently selected from the group of alkylene having 1 to 6 carbon atoms and arylene having 6 to 10 carbon atoms;
each R⁵ is selected from alkyl groups having 1 to 4 carbon atoms and phenyl groups; and n, m and p have the same meaning as above.

8. The polymer film according to any of the preceding embodiments, wherein the monomers according to general formula I are selected from monomers having the formulas Ia, Ib or Ic

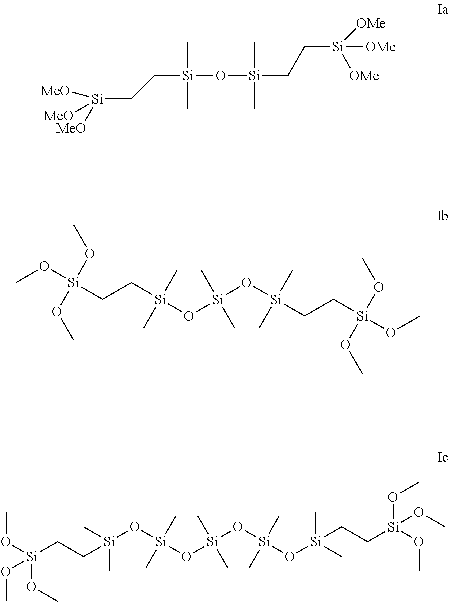

and combinations thereof.

9. The polymer film according to any of the preceding embodiments, obtained by homopolymerization of compounds of general formula I, such as compounds Ia, Ib or Ic.

10. The polymer film according to any of the preceding embodiments, obtained by copolymerization of compounds of general formula I with silane monomers, wherein the compounds of formula I in amount to at least 10 mol % of the total amount of silane monomers.

11. The polymer film according to any of the preceding embodiments, obtained by copolymerization of a compound of formula I with a compound of formula III

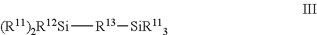

wherein
R¹¹ is a hydrolysable group, such as hydrogen, a halide, an alkoxy or an acyloxy group;
R¹² is hydrogen, an organic crosslinking group, a reactive cleaving group or a polarizability reducing organic group; and
R³ s a bridging linear or branched bivalent hydrocarbyl group.

12. The polymer film according to any of embodiments 1 to 10, obtained by copolymerization of a compound of formula I with a compound of formula IV

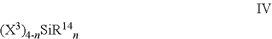

wherein
X³ is hydrogen or a hydrolysable group selected from halogen, acyloxy, alkoxy and OH groups;
R¹⁴ is selected from halogen, acyloxy, alkoxy and OH groups, and alkyl groups having 1 to 6 carbon atoms, vinyl groups having from 2 to 6 carbon atoms, and aryl groups having 6 carbon atoms; and
n is an integer having the same meaning as above.

13. The polymer film according to embodiment 10 to 12, wherein the molar ratio between compounds according to formula I and compounds of formula III or formula IV or both is in the range of 10:90 to 90:10, for example 20:80 to 80:20, in particular 40:60 to 60:40.

14. The polymer film according to any of the preceding embodiments, wherein the organic content of the polymer is in the range of 30 to 60 wt.-%, preferably less than 40 wt-%.

15. The polymer film according to any of the preceding embodiments, having a dielectric constant at 1 MHz of 2.7 or less.

16. The polymer film according to any of the preceding embodiments, wherein the dielectric constant of the polymer after curing is 2.45 or less, preferably 2.30 or less.

17. The polymer film according to any of the preceding embodiments, having an electric breakthrough voltage of 3.5 MV/cm or more.

18. The polymer film according to any of the preceding embodiments, having a thickness of less than 1 μm, in particular less than 500 nm, typically 50 to 350 nm.

19. The polymer film according to any of the preceding embodiments, having an RI greater than 1.4 determined at a wavelength of 633 nm.

20. A method of forming a polymeric film, comprising
hydrolyzing a first silicon compound having the formula I

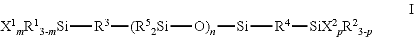

wherein X¹, X², X³, X⁴, R¹, R², R³, R⁴, R⁵, I and n, m, p have the same meaning as above, and
polymerizing the first silicon compound, optionally with at least one second silicon compound obtained by hydrolyzing a compound having the formula III

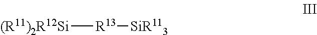

wherein
R¹¹ is a hydrolysable group, such as hydrogen, a halide, an alkoxy or an acyloxy group,
R¹² is hydrogen, an organic crosslinking group, a reactive cleaving group or a polarizability reducing organic group, and
R¹³ s a bridging linear or branched bivalent hydrocarbyl group.
and/or
having the formula IV

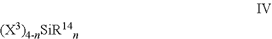

wherein X³, R¹⁴ and n have the same meaning as above, to produce a polymerized siloxane material and
shaping the polymerized siloxane material into a layer, which is cured into a film.

21. The method according to embodiment 20, comprising depositing the siloxane material in the form of a thin layer on a substrate; and curing the thin layer to form a film.

22. The method according to embodiment 21, wherein the substrate is a semiconductor substrate.

23. The method according to any of embodiments 20 to 22, wherein the polymeric film has a thickness of less than 1 μm, in particular less than 500 nm, typically 50 to 350 nm.

24. The method according to any of embodiments 20 to 23, wherein the polymeric film is cured at a temperature of 350° C. or more.

25. The method according to any of embodiments 20 to 24, comprising forming a polymeric film having a dielectric constant of 2.7 or less at 1 MHz.

26. A method for manufacturing a semiconductor device according to any of embodiments 20 to 25, said method comprising or consisting of the following steps:
depositing a metal layer;
depositing photoresist and auxiliary underlayers on top of the metal;
exposing the said photoresist stack to light or an electron beam through a mask to form a desired pattern;
developing the soluble parts of the photoresist and transferring the formed pattern to the metal layer by selective etch processes;
removing residual parts of the photoresist stack;
depositing and curing the low-k dielectric film; and
removing excess of deposited low-k dielectric film by an etch back or chemical mechanical polishing process.

27. The use of a polymeric film according to any one of embodiments 1 to 19 as a low dielectric constant film in a semiconductor device.

28. Semiconductor device comprising a polymeric film according to any one of embodiments 1 to 19 as a low dielectric constant film, in particular as a film having having a dielectric constant of 2.7 or less at 1 MHz.

### INDUSTRIAL APPLICABILITY

The present invention provides a method of manufacturing semiconductor devices comprising low dielectric constant films, wherein said films comprise polymers suitable as barrier layers for filling spaces between metal interconnects having a largest dimension of less than 30 nm, such as 10 to 20 nm. In particular, said metals are selected from cobalt (Co), molybdenum (Mo), tungsten (W) and ruthenium (Ru).

### REFERENCE NUMERALS

1=substrate
2=metal deposition
3=metal layer, e.g. Co or Ru
4=photoresist coating
5=photoresist—EUV-material
6=exposure and development
7=etching
8=photoresist stripping
9=dielectric coating
10=low k dielectric
11=substrate
12=dielectric coating
13=low k dielectric
14=etching
15=barrier material and metal coating
16=barrier material
17=metal, e.g. Cu

1-26. (canceled)

27. A method for manufacturing a polymer film, the method comprising:
polymerizing compounds, the compounds comprising compounds having the general formula I 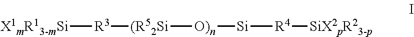
wherein
each X¹ and X² is independently selected from the group of hydrogen and organic or inorganic hydrolyzable groups;
each R¹ and R² is independently selected from the group of hydrocarbyl residues, which optionally are substituted;
each R³ and R⁴ is independently selected from the group of optionally substituted bridging linear or branched bivalent hydrocarbyl groups;
each R⁵ is selected from alkyl groups having 1 to 6 carbon atoms and aryl groups having 6 to 18 carbon atoms, said groups optionally being substituted;
n is an integer of 1 to 5;
m is an integer of 1 to 3; and
p is an integer of 1 to 3, to obtain a polymer,
shaping the polymer into a layer, and
curing the layer to form the polymer film.

28. The method according to claim 27, wherein in formula I, each X¹ and X² is independently selected from the group of hydrogen and hydrolysable groups selected from halogen, acyloxy, alkoxy and OH groups.

29. The method according to claim 27, wherein in formula I, each X¹ and X² is independently selected from the group of hydrogen and R⁷O—, wherein R⁷ stands for an alkyl having 1 to 6 carbon atoms.

30. The method according to claim 27, wherein in formula I, each R¹ and R² is independently selected from the group of linear, branched and cyclic alkyl groups having 1 to 10 carbon atoms, aryl groups containing 1 to 5 aromatic rings, optionally containing 1 to 3 heteroatoms, each optionally being substituted with 1 to 3 functional groups selected from halo, hydroxy, alkoxy, vinyl and acetyl groups.

31. The method according to claim 27, wherein in formula I, each R³ and R⁴ is independently selected from alkylene having 1 to 4 carbon atoms.

32. The method according to claim 27, wherein in formula I, n stands for an integer of 1, 2 or 4.

33. The method according to claim 27, wherein, in formula I,
each X¹ and X² is independently selected from the group of hydrogen and organic or inorganic hydrolyzable groups;
each R¹ and R² is independently selected from the group of hydrocarbyl residues;
each R³ and R⁴ is independently selected from the group of alkylene having 1 to 6 carbon atoms and arylene having 6 to 10 carbon atoms; and
each R⁵ is selected from alkyl groups having 1 to 4 carbon atoms and phenyl groups.

34. The method according to claim 27, wherein the compounds according to general formula I are selected from monomers having the formulas Ia, Ib or Ic 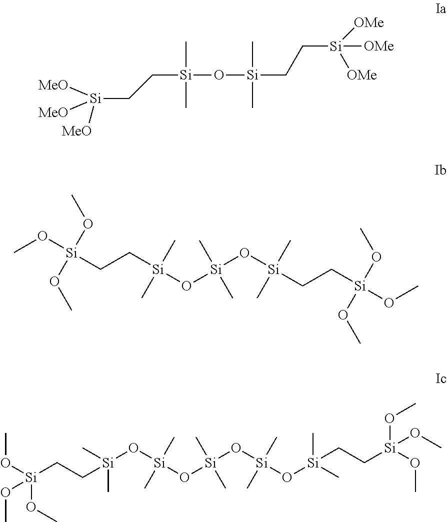
and combinations thereof.

35. The method according to claim 27, wherein the polymerizing is a homopolymerization of compounds of general formula I.

36. The method according to claim 27, wherein the polymerizing is a copolymerization of compounds of general formula I with silane monomers, wherein the compounds of formula I amount to at least 10 mol % of the total amount of silane monomers.

37. The method according to claim 27, wherein the polymerizing is a copolymerization of compounds of formula I with compounds of formula III 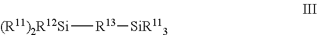
wherein
R¹¹ is a hydrolysable group;
R¹² is hydrogen, an organic crosslinking group, a reactive cleaving group or a polarizability reducing organic group; and
R¹³ is a bridging linear or branched bivalent hydrocarbyl group.

38. The method according to claim 27, wherein the polymerizing is a copolymerization of compounds of formula I with compounds of formula IV 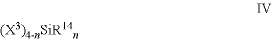
wherein
X³ is hydrogen or a hydrolysable group selected from halogen, acyloxy, alkoxy and OH groups;
R¹⁴ is selected from halogen, acyloxy, alkoxy and OH groups, and alkyl groups having 1 to 6 carbon atoms, vinyl groups having from 2 to 6 carbon atoms, and aryl groups having 6 carbon atoms; and
n is an integer from 1 to 5.

39. The method according to claim 37, wherein in the polymer obtained by the copolymerization of compounds of formula I and compounds of formula III, the molar ratio between the compounds according to formula I and the compounds of formula III is in the range of 10:90 to 90:10.

40. The method according to claim 27, wherein the organic content of the polymer is in the range of 30 to 60 wt.-%.

41. The method according to claim 27, wherein the polymer film has a dielectric constant at 1 MHz of 2.7 or less.

42. The method according to claim 27, wherein the polymer film has an electric breakthrough voltage of 3.5 MV/cm or more.

43. The method according to claim 27, wherein the polymer film has a thickness of less than 1 μm.

44. The method according to claim 27, wherein the polymer film has an RI greater than 1.4 determined at a wavelength of 633 nm.

45. The method according to claim 1, wherein the polymer film is cured at a temperature of 350° C. or more.

46. A polymer film obtained by a method according to claim 27.

47. A method for manufacturing a semiconductor device, the method comprising:
providing a substrate;
depositing a metal layer comprising one or more metals selected from cobalt (Co), molybdenum (Mo), tungsten (W) and ruthenium (Ru) on the substrate;
depositing photoresist and auxiliary underlayers on top of the metal layer:
exposing the photoresist stack to light or an electron beam through a mask to form a desired pattern;
developing soluble parts of the photoresist and transferring the formed pattern to the metal layer by selective etch processes;
removing residual parts of the photoresist stack;
depositing and curing the polymer film according to claim 27 on the substrate; and
removing excess of the polymer film by an etch back or chemical mechanical polishing process.
